(19) United States
(12) Patent Application Publication
(10) Pub. No.: US 2023/0387339 A1
(43) Pub. Date: Nov. 30, 2023

(54) MULTIPLE SOLAR CELL AND USE OF A MULTIPLE SOLAR CELL

(71) Applicants: Fraunhofer-Gesellschaft zur Förderung der angewandten Forschung e.V., München (DE); Albert-Ludwigs-Universität Freiburg, Freiburg (DE)

(72) Inventors: David LACKNER, Freiburg (DE); Oliver HÖHN, Freiburg (DE); Benedikt BLÄSI, Freibug (DE); Jens OHLMANN, Freiburg (DE); Frank DIMROTH, Freiburg (DE); Jonas SCHÖN, Freiburg (DE)

(73) Assignees: Fraunhofer-Gesellschaft zur Förderung der angewandten Forschung e.V., München (DE); Albert-Ludwigs-Universität Freiburg, Freiburg (DE)

(21) Appl. No.: 18/030,413

(22) PCT Filed: Oct. 1, 2021
(86) PCT No.: PCT/EP2021/077077

§ 371 Date: Apr. 5, 2023

(30) Foreign Application Priority Data
Oct. 6, 2020 (DE) 10 2020 126 116.0

(51) Int. Cl. H01L 31/0475; H01L 31/054

(52) U.S. Cl. CPC H01L 31/0475; H01L 31/0547; H01L 31/0725

(57) ABSTRACT

A multiple solar cell having at least two partial cells, at least being formed from a direct semiconductor, having an upper partial cell facing the light and a lower partial cell facing away from the light, an upper bandgap of the upper partial cell being greater than a lower bandgap of the lower partial cell, and an intermediate layer arranged on the lower partial cell side facing away from the light. An optical element including a lower mirror element is arranged on the intermediate layer side facing away from the light, and has a partial element having structural elements arranged in a lateral direction on the intermediate layer side facing away from the light. The structural elements have a mean spacing less than or equal to 1.3 times a spacing value that results from a ratio of a wavelength of the lower bandgap to a refractive index of the lower partial cell or the lower mirror element has a roughness having a root-mean-square value of less than 50 nm.

### CROSS-REFERENCE TO RELATED APPLICATIONS

This application is a 371 National Phase of International Application No. PCT/EP2021/077077, filed Oct. 1, 2021, which claims priority from German Patent Application No. 10 2020 126 116.0, filed Oct. 6, 2020, both of which are incorporated herein by reference as if fully set forth.

### TECHNICAL FIELD

The present invention relates to a multiple solar cell having at least two partial cells, at least one partial cell being formed from a direct semiconductor, having an upper partial cell facing the light and a lower partial cell facing away from the light, an upper bandgap of the upper partial cell being greater than a lower bandgap of the lower partial cell, and an intermediate layer being arranged on the side of the lower partial cell facing away from the light. Furthermore, the present invention relates to the use of a multiple solar cell for example in extraterrestrial systems, in terrestrial concentrator systems, in flying objects and/or in vehicles and/or thermophotovoltaics.

### BACKGROUND

Present-day multiple solar cells are primarily geared to a high efficiency and comprise a multiplicity of partial cells. The focus of special attention is, in particular, that the largest possible spectral range of a relevant spectrum, for example of solar radiation, is introduced into the multiple solar cell and correspondingly absorbed in the partial cells. In order to attain a corresponding absorption in the desired spectral range, it is therefore necessary to form the respective partial cells of the multiple solar cell with a corresponding thickness so that a virtually complete absorption can be ensured.

The measures mentioned above are accompanied by disadvantages, in particular with regard to the power and the production of the multiple solar cells. In this regard, for a complete absorption in a specific spectral range, it is necessary to form the respective partial cells with large layer thicknesses and a small number of defects in the layer. Therefore, the individual layers of the multiple solar cell are usually produced in an epitaxial method, for example by means of metal organic vapor phase epitaxy (MOVPE), since these methods make it possible to form high-quality layers with a correspondingly low defect density. However, the production of multiple solar cells is associated with high costs as a result.

For the efficiency of a solar cell, generally the operating temperature thereof is also of particular importance. In this regard, for example, an increased operating temperature of the solar cell by comparison with laboratory conditions (typically 25° C.) leads to a reduction of the open clamping voltage V_{oc}, as a result of which the possible drawing of power decreases. Cooling is technically demanding, precisely in extraterrestrial systems, since the systems operate in a vacuum in space and cooling cannot be effected by way of convection, but rather primarily only by way of thermal radiation.

Moreover, solar cells in extraterrestrial systems are often exposed to high-energy proton and electron radiation which can foster the formation of defects in the partial cells and thus lead to a power loss in the space solar cell. It is known, for example, that an influence of defects in the individual partial cells of a multiple solar cell can be reduced by the use of thin partial cells, since, on account of the smaller thickness, there is a very much less pronounced influence on the generation of electricity as a result of the reduction of the diffusion length of the minority charge carriers as a result of the defects present or the defects produced by radiation. What is disadvantageous, however, is that thin partial cells can absorb only part of the relevant radiation and part of the absorbable radiation thus remains unused, as a result of which the efficiency decreases overall.

In order to reduce the influence of defects produced by radiation and thus to increase the radiation hardness of the solar cell, DE 10 2016 208 113 A1, for example discloses forming a multiple solar cell with at least three pn junctions, the multiple solar cell comprising at least three partial cells and at least one partial cell having a layer which is arranged between an emitter layer and a base layer and which has a bandgap greater than the bandgap of the emitter layer and of the base layer. The radiation hardness of the solar cell can indeed be increased by these methods, however, heating of the multiple solar cell cannot be prevented as a result. Particularly radiation which enters the multiple solar cell and which cannot be absorbed by the partial cells can lead to significant heating of the multiple solar cell as a result of parasitic absorption within the multiple solar cell, which heating can lead to significant power losses particularly in applications in space, on account of the lack of convection.

### SUMMARY

It is therefore an object of the present invention to specify a multiple solar cell which allows a high absorption in the relevant spectral range and at the same time reduces heating of the multiple solar cell, with at the same cost-effective production.

This object and further objects are achieved by a multiple solar cell and also by a multiple solar cell each having one or more of the features disclosed herein. Moreover, the object is achieved by the use of the multiple solar cell having one or more of the features disclosed herein. Advantageous embodiments for the multiple solar cell are found below and in the claims.

The multiple solar cell according to the invention comprises at least two partial cells, at least one partial cell being formed from a direct semiconductor, having an upper partial cell facing the light, a lower partial cell facing away from the light, and an intermediate layer arranged on the side of the lower partial cell facing away from the light. In this case, an upper bandgap of the upper partial cell is greater than a lower bandgap of the lower partial cell. Consequently, given a typical use configuration, the upper partial cell faces the incident light and the lower partial cell is correspondingly arranged indirectly or directly on the side of the upper partial cell facing away from the incident light.

What is essential is that an optical element comprising a lower mirror element is arranged on a side of the intermediate layer facing away from the light, the optical element comprising a partial element having a plurality of structural elements arranged in a lateral direction directly or indirectly on the side of the intermediate layer facing away from the light. Furthermore, the partial element and the lower mirror element are formed from the same material, the structural elements having a mean spacing which is less than or equal to 1.3 times a spacing value, which spacing value results from a ratio of a wavelength assigned to the lower bandgap to a refractive index, in particular the real part thereof, of the lower partial cell.

The optical element and the integral formation of the partial element with the lower mirror element afford the possibility that radiation having a specific wavelength is no longer diffracted and/or scattered at the structured partial element, but rather is substantially reflected back. The radiation wavelength proceeding from which, or the specific range in which, a virtually complete reflection takes place can be selectively limited by the mean spacing being chosen to be less than or equal to 1.3 times the spacing value. In particular, this makes it possible for low-energy radiation to be reflected directly at the lower mirror element and indeed no longer diffracted and/or scattered in the lateral region of the partial cells. The low-energy range of the spectrum can thus emerge again on the side of the multiple solar cell facing the light.

The spacing value is considered to be, in particular, the value of the spacing between the center point or the center line of one structural element and the center point or the center line of a closest adjacent structural element, which value is averaged over the number of structural elements. In particular, in the case of regular structures having regularly arranged structural elements, in particular gratings, the spacing value is given by the grating period for example in the case of point gratings or in the case of line gratings or by the lattice plane spacing in the case of hexagonal gratings.

The further multiple solar cell according to the invention comprises at least two partial cells, at least one partial cell being formed from a direct semiconductor, having an upper partial cell facing the light, having a lower partial cell facing away from the light, and an intermediate layer arranged on the side of the lower partial cell facing away from the light. In this case, an upper bandgap of the upper partial cell is greater than a lower bandgap of the lower partial cell.

What is essential to this further solution is that an optical element comprising a lower mirror element is arranged on a side of the intermediate layer facing away from the light, the optical element comprising a partial element having a plurality of structural elements arranged in a lateral direction directly or indirectly on the side of the intermediate layer facing away from the light. Furthermore, the lower mirror element is embodied as a plane mirror having a roughness having a root-mean-square value of less than 50 nm, preferably less than 20 nm, at least one separating layer being formed between the partial element and the lower mirror element.

What is made possible, too, by virtue of the lower mirror element being embodied as a plane mirror having a very low root-mean-square value of the roughness is that the radiation is substantially directly reflected back in conjunction with little parasitic absorption at the lower mirror element. Furthermore, by virtue of the use of a separating layer, low-energy radiation may experience distinctly less influencing at the partial element, and so in the case of the further variant of the multiple solar cell, too, a large part of the low-energy radiation, in particular radiation having an energy in a range from less than the lower bandgap to one spectral end of the relevant incident spectrum, can leave the multiple solar cell indirectly or directly at the side facing the light.

The spectral end of the relevant incident spectrum corresponds to an energy, or a wavelength assigned to the energy, at which 90%, preferably 95%, particularly preferably 98%, of the incident radiation of the entire relevant spectrum is attained. For a solar spectrum as the relevant incident spectrum, for example, the spectral end of the relevant incident spectrum thus arises in the region of the end of the near infrared, in particular at a wavelength of approximately 2.5 μm.

The lateral direction arises as a plane perpendicular to the thickness of the multiple solar cell. The thickness of a partial cell is substantially smaller than the lateral dimensions thereof (width, length and/or diameter).

The separating layer is preferably formed from a low refractive index material, a real part of the refractive index of the low refractive index material being less than or equal to 1.5.

The upper and lower partial cells have at least one pn junction each, at least one tunnel diode preferably being formed between the upper partial cell and the lower partial cell, the thickness of said at least one tunnel diode preferably being significantly smaller than the thickness of a partial cell in the thickness direction.

The bandgap of a semiconductor material as an energy difference between the valence band and the conduction band of a semiconductor is a fundamental property of the material per se, which is influenced by the temperature, inter alia. The bandgap of a specific semiconductor material can be determined in particular on the basis of the spectral quantum efficiency, as is set out in Helmers et al., Bandgap determination based on electrical quantum efficiency, Applied Physics Letters 103, 032108 (2013).

The partial element of the optical element forms, by way of the structural elements, an optical structure at which radiation impinging on the partial element is corresponding diffracted, scattered and/or reflected.

The use of “transparent” for the characterization of a material does not presuppose that this material has transparent properties over the entire spectrum. In particular, transparent properties of a material may be present only in a partial spectrum, for example in the range of the solar spectrum of 100 nm to 2500 nm, or else only in a subrange of a partial spectrum.

With preference, at least one, preferably all, of the partial cells is/are formed from a material from the group of the III-V semiconductors. In particular, the partial cells are formed substantially on the basis of binary, ternary, quaternary and/or quintenary compounds from the group of the III-V semiconductors. These semiconductor materials make it possible, in a very wide energy range, which can be adapted in particular to the relevant spectral range, for example the solar spectral range, to make possible the highest possible absorption. Moreover, the materials from the group of the III-V semiconductors are direct semiconductors, which have a high absorption in the correspondingly relevant spectral range even in conjunction with small layer thicknesses.

In one preferred embodiment, the lower partial cell has a thickness of less than 1200 nm, preferably less than 750 nm, particularly preferably less than 500 nm. As a result of the corresponding embodiment of the optical element, the thickness of the lower partial cell can be correspondingly reduced, thereby in particular also enabling the production costs of the multiple solar cell to be reduced and the production process to be accelerated. Moreover, a small thickness reduces the influence of defects in the partial cells that can also be produced by high-energy proton and electron radiation.

One preferred embodiment is distinguished by the fact that at least one further partial cell having a bandgap between the upper and lower bandgaps is arranged between the upper and lower partial cells. The at least one further partial cell enables the absorption of the multiple solar cell to be correspondingly adapted to the incident spectrum relevant to the field of application of the multiple solar cell, in particular the solar spectrum, with the result that an improved efficiency and thus a higher power of the multiple solar cell are made possible. In particular, the multiple solar cell can comprise a total of three or four or five or else six partial cells.

With preference, the lower mirror element is formed from a metal, in particular from silver or gold. Noble metals, such as silver or gold, for example, can easily be applied, in particular vapor-deposited, onto the semiconductor structures produced, the layers having a high quality and being able to be applied with a low roughness. In particular, a root-mean-square value of the roughness of less than 50 nm, preferably less than 20 nm, can be attained as a result. Moreover, a metallic mirror element can also be used for contacting of the multiple solar cell.

Alternatively, the lower mirror element can also be embodied as a Bragg mirror, which is preferably applied directly after the production of the partial cells in a further process step. A Bragg mirror as the lower mirror element makes it possible that the lower mirror element can likewise be formed with a very high reflectivity.

Alternatively or preferably in combination, the intermediate layer is formed from a semiconductor material, in particular from a material from the group of the III-V semiconductors. In particular, said intermediate layer can be applied to the lower partial cell directly after the production thereof. The bandgap of the intermediate layer is preferably greater than the lower bandgap of the lower partial cell.

With preference, the lower mirror element has a thickness of 50 nm to 4 μm, preferably of 100 nm to 2 μm. The corresponding thickness of the lower mirror element ensures that light is no longer transmitted on the back side of the multiple solar cell.

Alternatively, the lower mirror element can also serve as a carrier of the multiple solar cell, the thickness of the lower mirror element in this case preferably being in the range of 5 μm to 50 μm.

One preferred embodiment is distinguished by the fact that the optical partial element is embodied as a square grating, a cross grating, a hexagonal grating or a point grating. Alternatively or preferably supplementarily, the optical partial element can be embodied as a tailored disorder structure, as set out for example in Hauser et al., Tailored disorder: a self-organized photonic contact for light trapping in silicon-based tandem solar cells, Opt. Express 28, 10909 (2020). By virtue of the embodiment of the partial element with its structural elements as a corresponding grating or as a disorder structure, radiation in a specific spectral range of the incident relevant spectrum is correspondingly diffracted and/or scattered at the partial element, such that these spectral ranges are not directly reflected back. The embodiment of the optical partial element as a corresponding grating additionally makes it possible for low-energy radiation or at least one range of this radiation which cannot be absorbed by the partial cells not to be diffracted and/or scattered and thus to be correspondingly reflected back by the lower mirror element. In particular, the choice of the mean spacing value makes it possible to selectively adjust the radiation energy proceeding from which diffraction and/or scattering are/is no longer effected since e.g. higher orders of diffraction no longer exist.

In the case of the embodiment of the grating structure as a cross grating, the grating lines can be formed at right angles or else indeed not at right angles with respect to one another.

Preferably, the structural elements of the partial element are arranged regularly or irregularly. As a result of the corresponding arrangement of the structural elements, the properties of the optical partial element can be correspondingly influenced. In particular, in this case, the energy proceeding from which radiation that enters the multiple solar cell is no longer diffracted and/or scattered can be adjusted or a certain transition range can be defined.

In particular, the structural elements can be arranged regularly, the mean spacing in the case of a regular arrangement of the structural elements resulting in particular from the spacing of the center points of closest structural elements. Alternatively, the structural elements can also be arranged irregularly, the mean spacing resulting from the mean of the spacing of two closest adjacent structural elements over the multiplicity of structural elements.

The structural elements can be embodied in particular as a parallelepiped, cube or cylinder having a rectangular, square or round or oval base. Alternatively or in particular supplementarily, the structural elements can also be embodied as a pyramid, cone, truncated pyramid or truncated cone or a modified form thereof and can have in particular an irregular base.

Alternatively or with preference in combination, the structural elements have a thickness of between 50 nm and 400 nm, preferably between 100 nm and 300 nm. The structural elements are introduced for example by way of selective dry-chemical or wet-chemical etching processes or the application of inverse structures, between which the actual structural elements are finally formed.

One preferred embodiment is distinguished by the fact that the structural elements are embodied as squares, grating lines, grating points and/or as scattering centers, in particular as nanoparticles. The partial element or the grating structure is thus formed by the structural elements.

The use of nanoparticles as scattering centers makes it possible to apply these to the lower partial cell and to effect a random distribution in a lateral direction directly or indirectly along the intermediate layer. The influence of the nanoparticles or the influence of the partial element with its structural elements on the radiation that enters the multiple solar cell can be correspondingly adjusted by way of the size and the number of the nanoparticles.

One preferred embodiment of the multiple solar cell is distinguished by the fact that at least one optical component, in particular a glass and/or an antireflection layer and/or an upper mirror element, is arranged on a side facing the light above the upper partial cell. The optical component above the upper partial cell makes it possible that radiation outside the spectral range relevant to the multiple solar cell is at least partly reflected and thus cannot even penetrate into the multiple solar cell in the first place. Moreover, the optical component protects the underlying partial cells from external influences that could reduce the efficiency of the partial cells. In particular, the optical components can have a high absorption and/or a high emission for specific spectral ranges.

The upper mirror element as optical component is preferably embodied in such a way that in the incident spectral range relevant to the multiple solar cell, in particular for radiation having an energy greater than the lower bandgap which impinges on the upper mirror element substantially perpendicularly, said upper mirror element is transmissive, but for radiation which has entered the multiple solar cell and been reflected by the lower mirror element, which radiation usually impinges on the upper mirror element at an angle, said upper mirror element has a high reflection in the direction of the lower mirror element.

In one advantageous form of embodiment of the multiple solar cell, the optical component has a transmission—weighted with the photon number of the radiation—for radiation having an energy greater than or equal to the lower bandgap of at least 85%, preferably of at least 90%, particularly preferably of at least 93%. As a result, radiation absorbable by the partial cells can be transmitted through the optical components into the multiple solar cell.

In a further advantageous form of embodiment of the multiple solar cell, the at least one optical component has an absorption—weighted with the energy of the radiation—for radiation having an energy in the range from less than the lower bandgap to one spectral end of the relevant incident spectrum of less than 15%, preferably less than 10%. As a result of the low absorption for radiation which is outside the absorption range of the partial cells of the multiple solar cell up to the spectral end of the relevant incident spectrum, radiation in the aforementioned range can indeed be transmitted through the optical components, but on the other hand it is also ensured that this radiation is not absorbed in the optical components and can also emerge from the multiple solar cell again. As a result, it is possible to avoid in particular heating of the multiple solar cell as a result of the absorption of radiation in the range from less than the lower bandgap to the spectral end of the relevant incident spectrum. By way of example, for a solar spectrum such as AM0 or AM1.5 as relevant incident spectrum, the spectral end can be the spectral end of the near infrared at a wavelength of approximately 2.5 μm.

Particularly advantageously, besides the optical component, all components of the multiple solar cell have the property that they have an energy-weighted absorption for radiation in the range from less than the lower bandgap to a spectral end of the relevant incident spectrum of less than 15%, preferably less than 10%. Consequently, the radiation from the aforementioned range between the lower bandgap and the spectral end of the relevant incident spectrum can indeed penetrate through the multiple solar cell, but the low absorption means that the multiple solar cell is only slightly heated by the radiation from this range.

In yet another advantageous form of embodiment of the multiple solar cell, the optical component has an emission of radiation in the mid-infrared range, in particular for radiation having a wavelength of greater than 3 μm, preferably greater than 5 μm, of greater than 90%, preferably of greater than 95%, particularly preferably of greater than 98%. In particular, besides the optical components, the multiple solar cell has overall components having an emission of radiation in the mid-infrared range, in particular for radiation having a wavelength of greater than 3 μm, preferably greater than 5 μm, of greater than 90%, preferably of greater than 95%, particularly preferably of greater than 98%. Precisely as a result of a high emission of radiation having a wavelength of greater than 3 μm, radiative cooling of the multiple solar cell can be effectively implemented. In particular, the optical component and/or the multiple solar cell overall can have an emission of radiation right into the range of a wavelength of approximately 60 μm.

In one preferred embodiment, the optical component and/or the entire multiple solar cell are/is embodied in such a way that the latter has a high emission of radiation at least in a range around the maximum of the spectral radiant emittance according to Planck's radiation law.

With preference, the partial cells are contacted by way of contacts at the side of the multiple solar cell facing away from the light, in particular by means of metal wrap through technology (MWT). By virtue of contacts on the back side of the multiple solar cell, it is possible to avoid covering the front side and thus the side of the multiple solar cell facing the light, as a result of which the efficiency of the multiple solar cell can be increased.

Alternatively, however, contacts can also be formed on the front side of the multiple solar cell and thus on the side facing the light.

In a further preferred form of embodiment, the optical partial element and the lower mirror element are formed from a transparent conductive oxide, for example indium tin oxide.

In a further preferred form of embodiment, the mean spacing of the structural elements is less than or equal to 1.2 times the spacing value and/or greater than or equal to 0.8 times, preferably 0.9 times, the spacing value. The corresponding choice of the mean spacing of the structural elements achieves the effect that the impinging radiation is correspondingly selectively scattered and/or diffracted or no further influencing actually occurs, such that the radiation is just reflected back.

With preference, the mean spacing is between 230 nm and 450 nm, preferably between 250 nm and 400 nm. For this mean spacing of the structural elements, influencing of the radiation up to an energy corresponding to the lower bandgap can be attained in particular for partial cells based on III-V semiconductors. Moreover, radiation having an energy which is less than the lower bandgap is substantially reflected without influencing at the optical element, as a result of which this radiation can in particular emerge again at the side of the multiple solar cell facing the light.

A further advantageous form of embodiment is distinguished by the fact that a region of the spacing between the structural elements is filled by a dielectric material, the dielectric material preferably being embodied as transparent or non-absorbing, thereby making it possible to avoid heating as a result of absorption of radiation. The dielectric material can be, in particular, silicon oxide (SiO), titanium oxide (TiO), silicon nitride (SiN), indium tin oxide (ITO), or indium zinc oxide (IZO) or aluminum zinc oxide (AZO), the photoresist SU-8 or polymers such as, for example, propropylene (PP), polystyrene (PS), polymethyl methacrylate (PMMA) or polyimide. Alternatively, the material in a region of the spacing between the structural elements can be a gas, in particular air, or vacuum.

Alternatively or preferably supplementarily, a region of the spacing between the structural elements is filled by a resist, in particular a photoresist. In particular, the resist used can be used for structuring at the side of the intermediate layer facing away from the light, the structuring serving for the later formation of the structural elements. In this regard, it is possible, for example, for a corresponding structure having the corresponding structural elements to be formed by means of UV nanoimprint lithography (NIL). One exemplary process for structuring is set out for example in Cariou et al., III-V-on-silicon solar cells reaching 33% photoconversion efficiency in two-terminal configuration, Nature Energy 3, 326-333 (2018) or in Chen et al., A 19.9%-efficient ultrathin 205 nm-thick GaAs Solar Cell with a Silver Nanostructured Back Mirror, Nature Energy 4, 761-767 (2019).

Further alternatively or preferably supplementarily, a region of the spacing between the structural elements is filled by a semiconductor material having a bandgap which is preferably greater than the lower bandgap. Preferably, said material is gallium indium phosphide (GaInP), aluminum gallium arsenide (AlGaAs), gallium indium arsenide phosphide (GaInAsP), aluminum gallium indium arsenide phosphide (AlGaInAsP). The semiconductor material used for the region of the spacing between the structural elements can be produced in particular as early as during the epitaxy of the intermediate layer or can be applied to the intermediate layer directly after the formation thereof and can be structured by means of dry-chemical or wet-chemical etching processes.

In a further preferred embodiment, the optical partial element and the intermediate layer are formed from the same material, in particular from the same semiconductor material. In this case, the partial element is formed by way of an etching process in which firstly the intermediate layer with a larger thickness is applied to the lower partial cell over the whole area and then a selective etching process is carried out to form the corresponding structure. For a selective etching process, it may in turn be necessary to apply a resist to the whole-area intermediate layer, to structure said resist to form an etching mask, for example by means of nanoimprint lithography (NIL), and then to carry out one or more etching processes to form the structural elements, the resist optionally being completely removed after the formation of the structural elements of the partial element made from the semiconductor material.

Alternatively or preferably in combination, the partial element is formed by a resist, in particular a photoresist. In this case, the resist can be applied to the intermediate layer selectively, in particular for the corresponding production of the structure, or likewise initially over the whole area, and then, in particular by way of a nanoimprint lithography process and a selective etching process for residual resist removal, a corresponding structure is produced in the resist itself and not actually in the intermediate layer, as is set out in Cariou et al. or Chen et al., as mentioned above. This enables simpler process control, in particular, since only structuring with the resist is effected and structuring of the intermediate layer is not required.

In one preferred embodiment, a region of the spacing between the structural elements is filled by the separating layer. The separating layer thus achieves the effect that the intermediate regions between the structural elements are filled and a correspondingly plane mirror can be applied as the lower mirror element. In particular, the separating layer serves to ensure that a surface which is as smooth and level as possible is formed below the structural elements, thereby making it possible in particular to form a plane mirror having a low root-mean-square value of the roughness.

One advantageous form of embodiment of the multiple solar cell is distinguished by the fact that the structural elements have a mean spacing which is less than a wavelength assigned to the lower bandgap, or have a mean spacing which is less than or equal to 1.3 times a spacing value, the spacing value resulting from a ratio of a wavelength assigned to the lower bandgap to a refractive index, in particular the real part thereof, of the lower partial cell. What is achieved by this mean spacing is that radiation having an energy which is greater than or equal to the lower bandgap is correspondingly diffracted and/or scattered at the optical partial element such that it passes through at least the lower partial cell at least twice, preferably at least three times, particularly preferably at least four times.

Although radiation having an energy which is less than the lower bandgap can also be diffracted and/or scattered at these structural elements having the mean spacing which is less than a wavelength assigned to the lower bandgap, this radiation is reflected by the plane mirror substantially in the direction of the side of the multiple solar cell facing the light and can leave the multiple solar cells substantially without absorption.

In particular, the multiple solar cell overall is embodied in such a way that a parasitic absorption of radiation having an energy in the range from less than the lower bandgap to the end of the relevant incident spectrum per interaction with the lower mirror element is in the range of less than 5%, preferably less than 2%. Particularly preferably, the parasitic absorption of radiation having an energy in the range from less than the lower bandgap to the end of the relevant incident spectrum in the multiple solar cell overall is less than 25%, preferably less than 20%.

Advantageously, the separating layer is conductive, or for the contacting of the intermediate layer, point contacts are formed in the separating layer between the intermediate layer and the lower mirror element. By virtue of a conductive separating layer, contacting of the intermediate layer takes place automatically, without the need for further process steps. The formation of point contacts in the separating layer can be effected by way of processes known per se.

One advantageous embodiment is distinguished by the fact that the separating layer is formed from a semiconductor material, preferably amorphous silicon, or a titanium oxide, preferably titanium dioxide, or a preferably transparent conductive oxide, for example indium tin oxide (ITO) or indium zinc oxide (IZO) or aluminum zinc oxide (AZO). The preferably transparent conductive oxides have a sufficient conductivity, and so there is no need for point contacts for the contacting of the multiple solar cell, in particular of the intermediate layer.

Forming the separating layer from a semiconductor material such as amorphous silicon or titanium dioxide also achieves the effect that at the interface between the separating layer and the optical partial element, great scattering and/or diffraction occur(s) at least for radiation having an energy which is greater than the lower bandgap. Moreover, these materials can be applied to the multiple solar cell in a simple manner in terms of process engineering.

Alternatively or preferably in combination, the separating layer is formed from a preferably transparent dielectric material, for example silicon dioxide. By virtue of the preferably transparent dielectric material, in particular a conductivity between the intermediate layer and the lower mirror element is avoided and contacting is effected solely by way of the formation of point contacts in the separating layer.

Preferably, a planarization layer is arranged between the separating layer and the lower mirror element, the planarization layer preferably being formed from a polymer, for example from SU-8, PMMA, PS, polyimide, or from a dielectric, for example SiO, TiO, SiN or zinc sulfide (ZnS), or a Sol-Gel-based material, or a preferably transparent conductive oxide. In particular, the planarization layer can be formed from indium tin oxide (ITO), or indium zinc oxide (IZO), or aluminum zinc oxide (AZO). The planarization layer in turn makes it possible firstly to form the lower mirror element as a plane mirror having a root-mean-square value of the roughness of less than 50 nm, preferably less than 20 nm, influences such as undulations or the like between the separating layer and the lower mirror element also being able to be compensated for by means of the planarization layer. In particular, a planarization layer is advantageous if the separating layer cannot be formed with the corresponding quality and with correspondingly low roughness at the interface with the lower mirror element. Moreover, the planarization layer allows the separating layer to be able to be formed from a high refractive index material, such that it is possible to attain corresponding refraction, diffraction and/or scattering at the structural elements, in particular for radiation having an energy which is greater than the lower bandgap.

The planarization layer is preferably formed from a low refractive index material, the separating layer in this case preferably being formed from a material having a different real part of the refractive index than the planarization layer, in particular from a high refractive index material. In the present case, high refractive index denotes a material whose real part of the refractive index is greater than 1.5, preferably greater than 2, particularly preferably greater than 2.5.

One advantageous form of embodiment of the multiple solar cell is distinguished by the fact that the separating layer and/or the planarization layer have/has a thickness of between 100 nm and 300 nm, preferably around 200 nm, the thickness for the separating layer resulting from a spacing between an end of the structural element facing away from the light and the lower mirror element or the planarization layer. By virtue of the corresponding thickness between the lower mirror element and the structural elements, it is possible to attain a sufficiently smooth surface by way of the planarization layer, such that a plane mirror as the lower mirror element can be applied with a corresponding high quality and with a low root-mean-square value of the roughness.

Furthermore, the present application relates to the use of a multiple solar cell in accordance with any form of embodiment or preferred form thereof as explained above in extraterrestrial systems and/or in terrestrial concentrator systems and/or flying objects and/or vehicles and/or in thermophotovoltaics. In particular, the multiple solar cells are used in satellites or other space objects. Suitable flying objects are preferably unmanned systems such as pseudo-satellites or drones as well as manned flying systems such as aircraft.

### BRIEF DESCRIPTION OF THE DRAWINGS

Further advantageous features and embodiments of the multiple solar cell according to the invention are explained below on the basis of exemplary embodiments and with reference to the figures.

In the figures:

FIG. 1 shows a first embodiment of a first variant of a multiple solar cell according to the invention

FIG. 2 shows a further embodiment of a first variant of a multiple solar cell according to the invention;

FIG. 3 shows one embodiment of a second variant of a multiple solar cell according to the invention

FIG. 4 shows a further embodiment of a second variant of a multiple solar cell according to the invention

FIG. 5 shows yet another embodiment of a second variant of a multiple solar cell according to the invention

FIG. 6 shows yet another embodiment of a second variant of a multiple solar cell according to the invention

FIG. 7 shows yet another embodiment of a second variant of a multiple solar cell according to the invention

FIG. 8A shows a plan view of one embodiment of the partial element;

FIG. 8B shows a plan view of a further embodiment of the partial element; an

FIG. 8C shows a plan view of yet another embodiment of the partial element.

### DETAILED DESCRIPTION

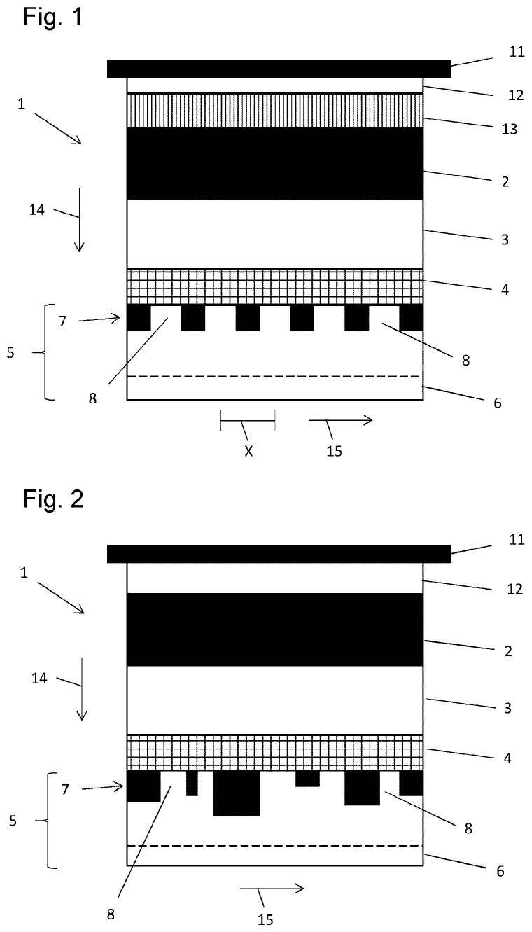

In FIGS. 1 to 8C, identical reference signs designate identical or identically acting elements.

FIG. 1 schematically shows a sectional illustration through a first variant of a multiple solar cell 1. The multiple solar cell 1 comprises an upper partial cell 2 facing the light, and also a lower partial cell 3 arranged downstream in the thickness direction 14, which partial cells have mutually different bandgaps. In this case, the upper bandgap of the upper partial cell 2 is greater than the lower bandgap of the lower partial cell 3. Furthermore, an intermediate layer 4 is arranged below the lower partial cell 3 in the thickness direction 14, the optical element 5 being directly adjacent to said intermediate layer. The optical element 5 comprises a lower mirror element 6 and also a partial element 7 constructed from a plurality of structural elements 8.

In the present case, the upper partial cell 2 as well as the lower partial cell 3 and also the intermediate layer 4 are direct semiconductors constructed from a material from the group of the III-V semiconductors. The upper partial cell 2 substantially consists of gallium indium phosphide (GaInP), the upper bandgap of which is in the range of approximately 1.9 eV. The thickness of the upper partial cell 2 is approximately 500 nm.

In the present embodiment, the lower partial cell 3 is formed from gallium arsenide (GaAs), the lower bandgap of which is in the range of approximately 1.4 eV. The wavelength assigned to the lower bandgap is approximately 870 nm. In the present case, the thickness of the lower partial cell 3 in the thickness direction 14 is approximately 450 nm to 800 nm, the thickness of this partial cell 3 being dependent on the absorption behavior, in particular. In this regard, the thickness of the lower partial cell 3, in a manner dependent on the reflection, absorption and transmission of the optical element 5 arranged below the lower partial cell 3 in the thickness direction 14, can also be in a range of less than 500 nm. The intermediate layer 4 adjacent to the lower partial cell 3 consists of the material aluminum gallium arsenide (AlGaAs), the bandgap of which is approximately 1.7 eV, which corresponds to a wavelength of approximately 730 nm assigned to this bandgap. In relation to the upper partial cell 2 and lower partial cell 3, the intermediate layer 4 has a thickness in the range of 200 to 500 nm.

The upper and lower partial cells 2, 3 have at least one pn junction each, at least one tunnel diode being formed between the upper partial cell 2 and the lower partial cell 3, the thickness of said at least one tunnel diode in the thickness direction 14 being less than 200 nm.

The optical partial element 7 with its structural elements 8, which are arranged with regular spacings with respect to one another as illustrated in FIG. 1 is formed from the same material as the lower mirror element 6. In the present case, the material silver was used for both the lower mirror element 6 and the optical partial element 7. The use of gold as material for the lower mirror element 6 and also the partial element 7 is likewise possible as well.

The regularly arranged structural elements 8 of the partial element 7 have a mean spacing X which is in the range of 270 to 300 nm. The spacing between two structural elements 8 results from the spacing of the respective center points of the structural elements 8. The mean spacing X is formed from the mean of all spacings between two adjacent structural elements 8 of the partial element 7. In the case of a regular arrangement of the structural elements 8, the spacing of adjacent structural elements 8 corresponds to the mean spacing X of the structural elements 8 of the partial element 7.

The choice of the mean spacing X for the present multiple solar cell 1 is of particular importance since the mean spacing X significantly influences the scattering and/or diffraction of light that arrives at the optical element 5 at the partial element 7. By virtue of the size and the arrangement of the structural elements 8 of the partial element 7 with a specific mean spacing X, the partial element 7 can be embodied in such a way that radiation having less than a specific energy is no longer diffracted and/or scattered at the optical partial element 7, but rather is substantially reflected at the optical element 5.

The determination of a suitable mean spacing X of the structural elements 8 is dependent on a spacing value A resulting from the chosen materials for the lower partial cell 3. In this case, the spacing value A results from the ratio of the wavelength assigned to the lower bandgap to the real part of the refractive index of the lower partial cell 3. The real part of the refractive index of gallium arsenide, which is used as material for the lower partial cell 3 in the embodiment illustrated in FIG. 1, has a value of approximately 3.5. Given a wavelength bandgap of 870 nm assigned to the lower bandgap, a spacing value A of approximately 250 nm thus results for this material combination.

Choosing the mean spacing X of the structural elements 8 of the optical partial element 7 to be less than or equal to 1.3 times the spacing value, hence less than or equal to 325 nm, makes it possible for radiation having an energy in the range of the lower bandgap to be directly reflected without diffraction or scattering at the optical element 5 (direct reflection).

The optical element 5 has overall a reflection of greater than 90% for radiation having an energy at least in the range from less than the lower bandgap to the end of the relevant incident spectrum, here to the spectral range of the near infrared at approximately 2.5 μm in the case of the solar spectrum AM0 as the relevant spectrum. As a result, radiation that is not absorbed by the multiple solar cell 1 and is outside the absorption range of the partial cells 2, 3 is directly reflected back at the optical element 5, such that this radiation can in turn substantially directly leave the multiple solar cell 1 at the side facing the light. The direct reflection makes it possible to avoid heating of the multiple solar cell 1 as a result of absorption of radiation that is not usable in the partial cells 2, 3, for example at defects of the multiple solar cell 1. The direct reflection of such radiation at the optical element 5 and the emergence of this radiation at the side of the multiple solar cell 1 facing the light make it possible for the multiple solar cell 1 to experience cooling at least indirectly.

Optical components such as a glass 11, an antireflection layer 12 or an upper mirror element 13 are formed in a manner arranged above the partial cell 2 in the thickness direction 14 on the side of the multiple solar cell 1 facing the light.

The optical components 11, 12, 13 have a transmission—weighted with the photon number of the radiation—for radiation having an energy which is greater than or equal to the lower bandgap of at least 90%. This ensures that radiation of the relevant incident spectrum that is usable by the multiple solar cell 1, in particular the radiation having an energy which is greater than or equal to the lower bandgap, can enter the multiple solar cell 1.

Moreover, the optical components 11, 12, 13 have an absorption—weighted with the energy of the radiation—of less than 10% for radiation having an energy in the range from less than the lower bandgap, which is at approximately 1.4 eV in the present case, to the spectral end of the near infrared for the solar spectrum as the relevant spectrum, which is at approximately 0.5 eV. The spectral range that is not usable by the partial cells 2, 3 can indeed enter the multiple solar cell 1, but at the same time can also emerge again from the multiple solar cell 1 without significant absorption after reflection at the optical element 5. As a result of low parasitic absorption, heating of the multiple solar cell 1 by radiation that is not absorbable by the partial cells 2, 3 is prevented, in particular.

In order to prevent further heating of the multiple solar cell 1, the at least one optical component 11, 12, 13 is embodied in such a way that it has an emission of radiation in the mid-infrared range of greater than 90% for radiation having a wavelength of greater than 5 μm. The optical component 11, 12, 13 thus indeed absorbs the mid-infrared radiation, on the one hand, but emits it again, on the other hand, by virtue of the high emission. Heating of the multiple solar cell 1 can likewise be avoided as a result. Besides the optical components 11, 12 13, the multiple solar cell 1 overall is embodied in such a way that radiation in the mid-infrared range is substantially absorbed and at the same time it has a high emission for the radiation in this range.

As illustrated in FIG. 1, the region between the structural elements 8 of the partial element 7 is filled by a material which is different than the structural elements 8. In the present case, the material arranged between the structural elements 8 is the photoresist SU-8 from Microchem Corp. During the production of the multiple solar cell 1, the photoresist is applied to the intermediate layer 4 over the whole area after the formation thereof and a corresponding structure is formed by means of UV nanoimprint lithography (NIL), residual resist being removed by means of an O₂ plasma etching step or a piranha etching step. Vapor deposition of a metal such as silver in the present case here finally results in the formation of the structural elements 8 or the optical partial element 7 and also the entire optical component 5, also comprising the lower mirror element 6. Besides the use of the photoresist SU-8, it is also possible to use other materials, in particular resists, which enable a corresponding structure to be formed on the side of the intermediate layer 4 facing away from the light by means of a similar process procedure. In particular, the spacing between the structural elements 8 need not necessarily be filled by a solid material. In this regard, it is also possible for the spacing to be filled with a gas as material, in particular air, or for a vacuum to prevail in the spacing region between the structural elements 8.

The structural elements 8 of the partial element 7 are arranged regularly in FIG. 1 and thus form individual grating points of a point grating on the side of the intermediate layer 4 facing away from the light. The individual grating points as structural elements 8 have a regular, rectangular or square base. In the present embodiment, the structural elements 8 of the partial element 7 are embodied overall as parallelepipeds, cubes or truncated pyramids. In the case of a regular arrangement of the structural elements 8, the mean spacing X results from the spacing of the center points of adjacent structural elements 8 as nearest neighbors.

Alternatively, the structural elements 8 can also be embodied as a pyramid, cone, truncated pyramid or truncated cone and in particular can also have an irregular base.

FIG. 2 illustrates a further embodiment of the multiple solar cell 1 according to the first variant, in which the structural elements 8 of the partial element 7 again have a mean spacing X which is less than or equal to 1.3 times a spacing value. A difference with respect to the embodiment illustrated in FIG. 1 resides in the arrangement and formation of the structural elements 8 of the optical partial element 7.

As illustrated in FIG. 2, the structural elements 8 are not arranged regularly, nor do they have a uniform size in the lateral direction 15, and they also have different thicknesses in the thickness direction 14. By comparison with the embodiment illustrated in FIG. 1, the spacing between the structural elements 8 for a reflection for radiation having an energy which is substantially less than the lower bandgap is varied in a specific range, the mean spacing X of the structural elements 8 of the partial element 7 likewise being of the order of magnitude of 270 nm to 300 nm. The mean spacing X again results from the calculated mean of the spacings between two adjacent structural elements 8 over the complete multiple solar cell 1.

In order to produce the corresponding partial element 7, firstly nanoparticles are applied from a solution on the side of the intermediate layer 4 facing away from the light, said nanop articles being distributed randomly on this side. The nanoparticles consist of a dielectric material and their size is in the range of 100 nm to 200 nm. After the solution has been evaporated, the nanoparticles are each arranged in stationary fashion on the side of the intermediate layer 4 facing away from the light, such that the formation of the structural elements 8 of the optical partial element 7 and of the optical element 5 overall is achieved by vapor deposition of a metal. Alternatively, a transparent conductive oxide can also be applied instead of the metal.

In an alternative production process for the partial element 7 having an irregular structure, it is likewise possible to use a self-organization process proceeding from a mixture of different polymers such as PMMA and PS, for example, in which case, after a layer composed of the mixture has been applied to the side of the intermediate layer 4 facing away from the light, a polymer is once again dissolved or etched, resulting in the formation of a corresponding self-organized structure. The structural elements 8 of the optical partial element 7 and accordingly the optical component 5 are formed once again by vapor deposition of a metal or a transparent conductive oxide.

Besides an irregular, random arrangement of the structural elements 8, the shape thereof is also embodied irregularly. In this regard, the embodiment of structural elements 8 having different shapes is made possible by the random arrangement of the nanoparticles or by the self-organization. In the present case, the width of the individual structural elements 8 extending in the lateral direction 15 is in the range of between 100 nm to 300 nm. In this case, the width is substantially determined by the regions which fill the spacing between the structural elements 8, which regions, in terms of process engineering in the first variant of the multiple solar cell 1 illustrated in FIGS. 1 and 2, are applied to the side of the intermediate layer 4 facing away from the light before the formation of the structural elements 8.

The multiple solar cell 1 is contacted via its underside. By virtue of the partial element 7 and also the lower mirror element 6 being formed from metal, the intermediate layer 4 of the multiple solar cell 1 is contacted directly, and so there is no need for further elements for the contacting of the intermediate layer 4, in particular point contacts.

The partial cells 2, 3 are contacted via the side of the upper partial cell 2 facing the light. Furthermore, there is also the possibility of the partial cells 2, 3 likewise being contacted via the side of the multiple solar cell 1 facing away from the light, by means of metal wrap through contacts, as is set out for example in the document Salvetat et al., III-V multi-junction solar cell using metal wrap through contacts, AIP conference proceedings 1766, 060004 (2016). As a result, the efficiency of the multiple solar cell 1 can be increased further.

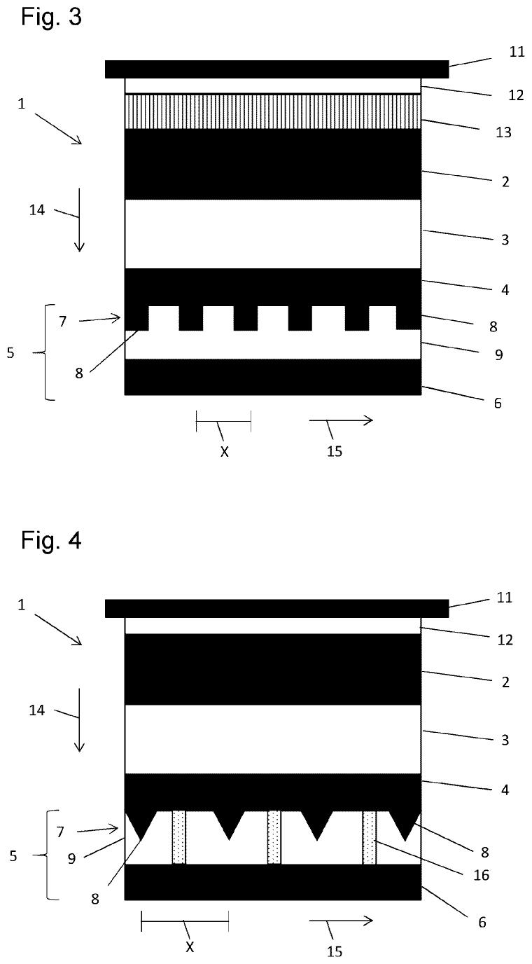

FIG. 3 illustrates a first embodiment of the further variant of the multiple solar cell 1. The construction of the multiple solar cell 1 illustrated in FIG. 3 is similar to the structural construction as illustrated in FIG. 1 or 2, there being differences in the optical element 5 and the construction thereof, but they fulfil the same objective and purpose.

The optical element 5 comprises an optical partial element 7 having a plurality of structural elements 8 and also a lower mirror element 6, the lower mirror element 6 being embodied as a plane mirror having a roughness having a root-mean-square value of less than 50 nm. Furthermore, a separating layer 9 is formed between the intermediate layer 4 and the plane mirror as the lower mirror element 6, which separating layer firstly fills the regions and spacings forming between the structural elements 8 and at the same time also forms a spacing in the thickness direction 14 between the structural elements 8 and the lower mirror element 6.

In the present embodiment, the separating layer 9 is formed from the material indium tin oxide (ITO), which is a transparent conductive oxide. The use of transparent conductive oxides such as indium tin oxide or alternatively indium zinc oxide (IZO) or aluminum zinc oxide (AZO) has the advantage that the intermediate layer 4 is simultaneously contacted via the separating layer 9. Moreover, transparent conductive oxides can be yielded with a high quality, in particular with a surface having low roughness, with the result that a correspondingly plane mirror as the lower mirror element 6 having a root-mean-square value of the roughness of less than 50 nm can be correspondingly applied on the side of the separating layer 9 facing away from the light. In this case, the separating layer 9 is formed from a low refractive index material. The lower mirror element 6 is again formed from silver, the thickness thereof being at least 200 nm, with the result that transmission of light is prevented. Alternatively, the lower mirror element 6 can also be formed from a Bragg mirror.

In the embodiment illustrated in FIG. 3, the structural elements 8 of the optical partial element 7 are formed by the same material AlGaAs as the intermediate layer 4. In order to produce the structural elements 8, in terms of process engineering, in this case, firstly a significantly thicker intermediate layer 4 is applied, into which the corresponding structural elements 8 are introduced by way of lithography methods and wet-chemical or dry-chemical etching processes. As illustrated in FIG. 3, the optical structural elements 8 again have a regular arrangement, the mean spacing thereof being in the range of between 270 nm and 500 nm. The thickness in the thickness direction 14 of the structural elements 8 is in the range of between 150 nm to 300 nm.

In the further variant of the multiple solar cell 1, as illustrated in FIG. 3, the mean spacing X of the structural elements 8 is significantly greater than the mean spacing X of the embodiment of the multiple solar cell 1 illustrated in FIGS. 1 and 2. By virtue of the significantly greater mean spacing X between the structural elements 8, radiation having an energy which is less than the lower bandgap indeed also experiences, at least partly, diffraction and/or scattering at the optical partial element 7, although reflection for this radiation of more than 98% is ensured by the plane mirror as the lower mirror element 6. Consequently, radiation that enters the multiple solar cell 1 is optimally reflected at the surface of the plane mirror as the lower mirror element 6. As a result of the diffraction and/or scattering at the partial element 7 and also the reflection at the plane mirror as the lower mirror element 6, a significant path lengthening within the multiple solar cell 1 is attained for the radiation. As a result, the lower partial cell 3 can be formed with a smaller thickness since a sufficiently large absorption section for a complete absorption of the radiation that is usable by the lower partial cell 3 is attained by virtue of the path lengthening.

Besides a low root-mean-square value of the roughness of the lower mirror element 6 for a corresponding reflection, the other constituent parts of the multiple solar cell 1 also have a high quality, and so the parasitic absorption for radiation having an energy in a range from less than the lower bandgap to the spectral end of the near infrared for the solar spectrum as the relevant incident spectrum is low in the entire multiple solar cell 1. The parasitic absorption per interaction of the radiation with the lower mirror element 6 as a result of the high-quality layers is in a range of less than 5%, and so even upon multiple reflection of radiation that is not absorbable by the partial cells 2, 3, this radiation is not absorbed at defects or other absorption centers of the multiple solar cell 1. In particular, the parasitic absorption for this radiation is less than 20% for the entire multiple solar cell. This radiation can be emitted again at the side of the multiple solar cell 1 facing the light and can emerge from the multiple solar cell 1. Consequently, an optical element 5 comprising a partial element 7, a separating layer 9 and a plane mirror as the lower mirror element 6 also achieves the result that heating by non-usable radiation in the multiple solar cell 1 is likewise avoided overall.

FIG. 4 illustrates a further embodiment of the further variant of the multiple solar cell 1. The latter, in terms of construction, is again similar to the construction as illustrated in FIG. 3, with the differences that the separating layer 9 is embodied as nonconductive material and the structural elements 8 are embodied as conical elements, the vertex of which is directed in the direction of the lower mirror element 6. In the present embodiment, for the separating layer 9, the material silicon dioxide (SiO₂) is used, on whose side facing away from the light a plane mirror composed of silver as the lower mirror element 6 is again applied.

The separating layer 9 composed of silicon dioxide fills the region between the structural elements 8 of the optical partial element 7 and furthermore has a further thickness in the thickness direction 14 of approximately 200 nm, which corresponds to the distance between the surface of the structural elements 8 facing away from the light and the plane mirror as the lower mirror element 6.

The intermediate layer 4 is contacted via point contacts 16 on account of the lack of conductivity of the separating layer 9. In this case, the point contacts 16 can initially be formed by means of lithography or a laser and subsequently be completed by way of a metallization step.

In the embodiment illustrated in FIG. 4, the mean spacing X of the structural elements 8 of the optical partial element 7 is approximately 800 nm to 850 nm and is thus in the range of the wavelength assigned to the lower bandgap.

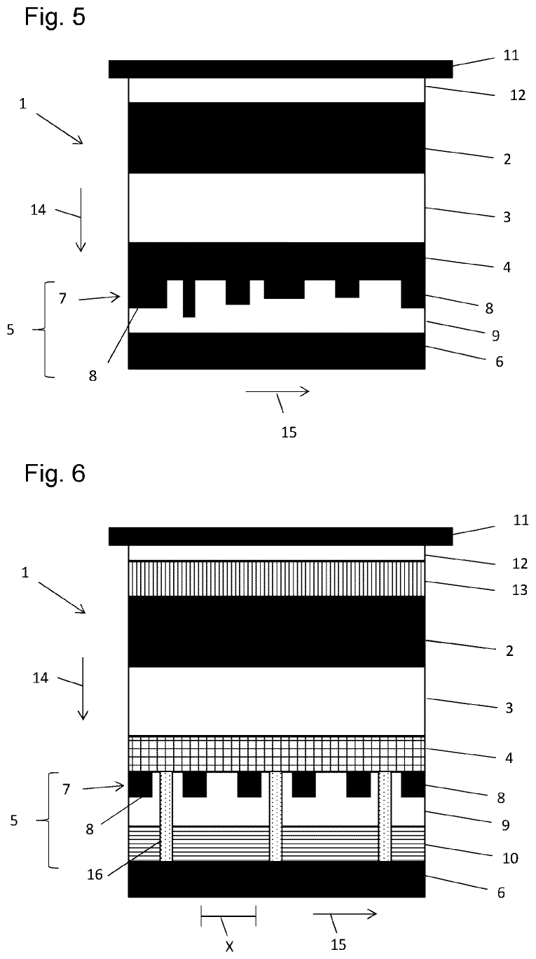

Besides a regular arrangement of the structural elements 8 in the optical element 5, in the further variant of the multiple solar cell 1, too, the structural elements 8 can be formed irregularly in the lateral direction 15 at the side of the intermediate layer 4 facing away from the light, as is illustrated in FIG. 5. In addition, the structural elements 8 again have different thicknesses in the thickness direction 14.

In order to form an irregular structure, firstly the intermediate layer 4 with a corresponding thickness is applied on the underside of the lower partial cell 3, and then nanop articles or other materials for structure definition are applied to the intermediate layer 4, which serve as a mask for the formation of the structural elements 8 and accordingly the optical partial element 7 in a subsequent wet-chemical or dry-chemical etching process.

Alternatively, the irregular structure can be implemented by employing the phase separation of two immiscible polymers such as polystyrene and polymethyl methacrylate, thus resulting in a stochastic arrangement of polystyrene elements, as is set out in Hauser et al. This stochastic arrangement can optionally be directly metallized.

By way of the separating layer 9, the spacings between the structural elements 8 are filled, and a layer going beyond the thickness of the structural elements 8 is formed, and a plane mirror as the lower mirror element 6 having a root-mean-square value for roughness of less than 50 nm and composed of gold of silver is subsequently applied by vapor deposition.

FIG. 6 illustrates a further embodiment of the further variant of the multiple solar cell 1. In contrast to the abovementioned embodiments of the further variant in FIGS. 3 to 5, the structural elements 8 in the embodiment now illustrated in FIG. 6 are not formed by the semiconductor material of the intermediate layer 4, but rather by a dielectric. In this case, as analogously also already set out above, the structural elements 8 are formed by whole-area application of a layer that completely covers the intermediate layer 4 by means of photoresist, corresponding structuring of the layer, for example by means of UV nanoimprint lithography, and a subsequent wet-chemical or dry-chemical etching process.

As illustrated in FIG. 6, the structural elements 8 are embedded into the separating layer 9, which is formed by lightly doped amorphous silicon in the present case. The use of amorphous silicon as the separating layer 9 then affords the advantage that this material has a very high refractive index and thus enables great scattering or diffraction precisely for radiation having an energy which is greater than the lower bandgap, with the result that this radiation experiences the largest possible path lengthening at least in the lower partial cell 3. This makes it possible to ensure that radiation that is absorbable by the partial cell 2, 3 is also absorbed in the partial cells 2, 3, even though at least the lower partial cell 3 has only a small thickness of approximately 1000 nm. Alternatively, the separating layer 9 can also be formed from a titanium oxide.

Furthermore, in the embodiment illustrated in FIG. 6, a planarization layer 10 is formed between the separating layer 9 and the lower mirror element 6. In the present case, the planarization layer 10 is formed from a polymer and makes it possible for the lower mirror element 6 to be embodied as a plane mirror having a very low roughness, in particular having a root-mean-square value of the roughness of less than 20 nm. By means of the planarization layer 10, the prerequisites for the deposition of a plane mirror as the lower mirror element 6 are thus provided, in particular for the case where the separating layer 9 cannot be formed with a corresponding surface between the separating layer 9 around the plane mirror, with the result that the plane mirror has low roughness.

In this case, the planarization layer 10 is formed from a low refractive index material, whereas the separating layer 9 is formed from a high refractive index material.

In order to enable the intermediate layer 4 to be contacted, the multiple solar cell 1 once again has point contacts 16 on account of lack of conductivity of the separating layer 9 and/or of the planarization layer 10, said point contacts being formed between the lower mirror element 6 and the intermediate layer 4.

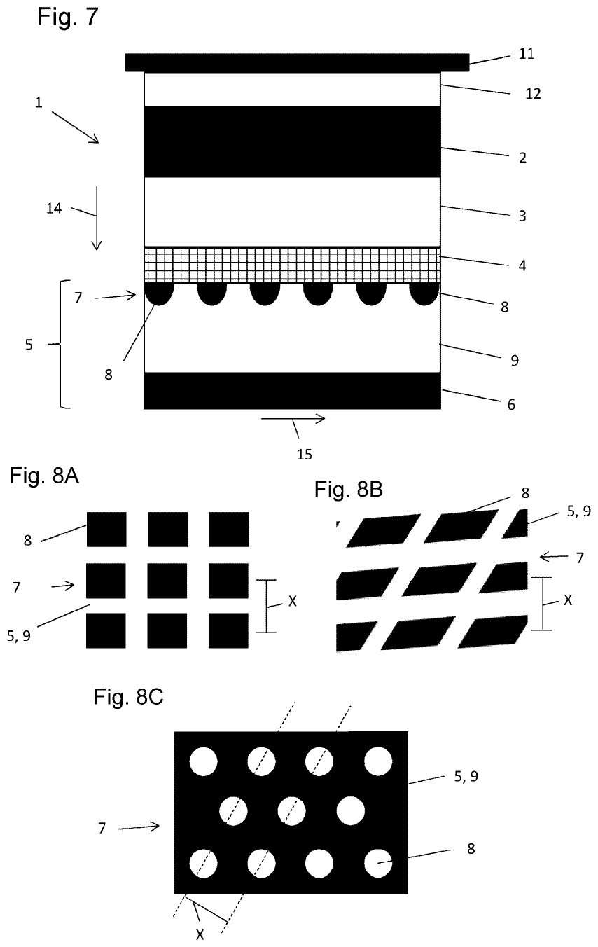

FIG. 7 illustrates yet another embodiment of the further variant of the multiple solar cell 1, which differs in that, by comparison with the embodiment illustrated in FIG. 6, the separating layer 9 and the planarization layer 10 are formed from the same material and this material has an intrinsic conductivity, and so it is possible to dispense with the formation of point contacts 16 for the contacting of the intermediate layer 4. Furthermore, the structural elements 8 are substantially embodied as hemispheres, the bases of which are arranged directly at the intermediate layer 4. Hemispherical structural elements can be used for the structuring of the partial element 7 by virtue of the use of nanoparticles or else can be formed as set out for example in Hauser et al., Tailored disorder: a self-organized photonic contact for light trapping in silicon-based tandem solar cells, Opt. Express 28, 10909 (2020).

In this embodiment, the structural elements 8 are formed from amorphous silicon or spherical beads of titanium oxide, which are applied from the wet phase on the side of the intermediate layer 4 facing away from the light. The spacings between the structural elements 8 are filled by application of a conductive oxide, which firstly enables the intermediate layer 4 to be contacted and secondly achieves planarization, with the result that it is possible to apply the lower mirror element 6 as a plane mirror having a low roughness.

The contacting of the upper and lower partial cells 2, 3 is implemented once again contacts on and below the solar cell. Alternatively, here as well there is the possibility of implementing the contacts via the side of the multiple solar cell 1 facing away from the light by way of metal wrap through contacts through the upper and partial cell 2,3.

As also in the case of the first variant of the multiple solar cell 1, the embodiments of the further variant of the multiple solar cell 1 as illustrated in FIGS. 3 to 7 also have at least one optical component 11, 12, 13 on the side facing the light above the upper partial cell 2 of the multiple solar cell. This once again involves a glass 11, an antireflection layer 12 or an upper mirror element 13. Independently of the variant of the multiple solar cell 1, the optical components 11, 12, 13 for the further variant of the multiple solar cell have identical properties, and so reference is accordingly made to the embodiments mentioned above.

Alternatively, it is also possible for the multiple solar cell 1 not to have an optical component 11, 12, 13.

Independently of a variant of the multiple solar cell 1, the structural elements 8 are not limited to a specific shape. FIGS. 8A, 8B and 8C illustrate details of different embodiments of the partial element 7 having the structural elements 8 in plan view. In FIG. 8A, the structural elements 8 of the partial element 7 are formed with a rectangular base and form parallelepipedal structural elements 8 in the thickness direction 14, extending out of the plane of the drawing. Depending on the variant of the embodiment of the multiple solar cell 1, the region of the spacing between the structural elements 8 can be filled by a photoresist, a semiconductor material, a dielectric or by a gas such as air and can form part of the optical element 5. Particularly in the further variant of the multiple solar cell 1, the region of the spacing between the structural elements 8 corresponds is filled by the separating layer 9. The structural elements 8 are thus embedded into the optical element 5. Alternatively, a vacuum may also prevail in this region of the spacing between the structural elements 8.

In this case, on account of the regular arrangement of the structural elements 8, the mean spacing X results from the spacing of the center points of the structural elements 8. In this regard, the latter can be embodied in particular as points of a point grating which have a parallelepipedal, cubelike or half-round shape.

In the case of the half-round shape of the structural elements 8, the circular base bears directly against the intermediate layer 4, as is illustrated in FIG. 8C, and the rounding is formed in the direction of the lower mirror element 6. In this case, the structural elements 8 having the round base are formed regularly in rows, the adjacent row being formed offset, such that these form a hexagonal grating. In this case of the arrangement of the structural elements 8 in a hexagonal grating, the mean spacing X results from the lattice plane spacing of the grating, as illustrated in FIG. 8C.

Moreover, as illustrated in FIG. 8B, the structural elements 8 can have a trapezoidal base resulting from the specific manifestation of the intermediate regions between the structural elements 8. Moreover, the structural elements 8 can be embodied as conical or pyramidal elements, the vertex of which is directed in the direction of the lower mirror element 6, or truncated variants thereof. The exact form of embodiment of the structural elements 8 is substantially dependent on the materials used for the upper and lower partial cells 2, 3 and also the intermediate layer 4 and the materials of the optical element 5. In particular, the production process also has a great influence for the specific shape of the structural elements 8.

Moreover, the structural elements 8 can form a line grating or a hexagonal grating. In the case of a line grating, the spacing between two adjacent structural elements 8 is calculated from the spacing of the center lines of the adjacent structural elements 8. In the case of irregular line gratings, the mean spacing X is calculated by way of the mean of all spacings between the structural elements 8 of the entire multiple solar cell 1.

The research work that led to these results was sponsored by the European Union.

### LIST OF REFERENCE SIGNS

1 Multiple solar cell
2 Partial cell (upper)
3 Partial cell (lower)
4 Intermediate layer
Optical element
6 Lower mirror element
7 Partial element
8 Structural element
9 Separating layer
Planarization layer
11 Glass
12 Antireflection layer
13 Upper mirror element
14 Thickness direction
Lateral direction
16 Point contact
X Mean spacing

1. A multiple solar cell (1), comprising:
at least two partial cells (2, 3),
at least one of the partial cells (2, 3) being formed from a direct semiconductor, having an upper partial cell (2) facing light and a lower partial cell (3) facing away from the light, an upper bandgap of the upper partial cell (2) being greater than a lower bandgap of the lower partial cell (3), and an intermediate layer (4) being arranged on a side of the lower partial cell (3) facing away from the light,
an optical element (5) comprising a lower mirror element (6) arranged on a side of the intermediate layer (4) facing away from the light, the optical element (5) comprising a partial element (7) having a plurality of structural elements (8) arranged in a lateral direction (15) directly or indirectly on the side of the intermediate layer (4) facing away from the light, and
the partial element (7) and the lower mirror element (6) are formed from a same material, and the structural elements (8) have a mean spacing (X) which is less than or equal to 1.3 times a spacing value (A) resulting from a ratio of a wavelength assigned to the lower bandgap to a refractive index of the lower partial cell (3).

2. A multiple solar cell (1) comprising:
at least two partial cells (2, 3),
at least one partial cell (2, 3) being formed from a direct semiconductor, having an upper partial cell (2) facing light and a lower partial cell (3) facing away from the light, an upper bandgap of the upper partial cell (2) being greater than a lower bandgap of the lower partial cell (3), and an intermediate layer (4) being arranged on a side of the lower partial cell (3) facing away from the light,
an optical element (5) comprising a lower mirror element (6) arranged on a side of the intermediate layer (4) facing away from the light, the optical element (5) comprising a partial element (7) having a plurality of structural elements (8) arranged in a lateral direction (15) directly or indirectly on the side of the intermediate layer (4) facing away from the light, and
the lower mirror element (6) is embodied as a plane mirror having a roughness having a root-mean-square value of less than 50 nm, and at least one separating layer (9) being formed between the partial element (7) and the lower mirror element (6).

3. The multiple solar cell (1) as claimed in claim 1, wherein
at least one of the partial cells (2, 3) is formed from a group III-V semiconductor material.

4. The multiple solar cell (1) as claimed in claim 3, wherein
the lower partial cell (3) has a thickness of less than 1200 nm.

5. The multiple solar cell (1) as claimed in claim 1, further comprising
at least one further partial cell having a bandgap between the upper and lower bandgaps arranged between the upper and lower partial cells (2, 3).

6. The multiple solar cell (1) as claimed in claim 1, wherein at least one of a)
the lower mirror element (6) is formed from a metal, or
b) the intermediate layer (4) is formed from a semiconductor material, and the bandgap of the intermediate layer (4) is greater than the lower bandgap.

7. The multiple solar cell (1) as claimed in claim 1, wherein
the partial element (7) comprises as a square grating, a cross grating, a hexagonal grating, a point grating or as a tailored disorder structure.

8. The multiple solar cell (1) as claimed in claim 1,
wherein at least one of a)
the structural elements (8) are arranged regularly, or b) the structural elements (8) have a thickness in a thickness direction (14) of between 50 nm and 400 nm.

9. The multiple solar cell (1) as claimed in claim 1, wherein
the structural elements (8) a comprise at least one of squares, grating lines, grating points, or scattering centers.

10. The multiple solar cell (1) as claimed in claim 1, further comprising,
at least one of an optical component, an antireflection layer (12), or an upper mirror element (13) arranged on a side facing the light above the upper partial cell (3).

11. The multiple solar cell (1) as claimed in claim 10, wherein the optical component is provided and at least one of a)
the optical component (11, 12, 13) has a transmission—weighted with a photon number of radiation—for radiation having an energy greater than or equal to the lower bandgap of at least 85%,
b) the optical component (11, 12, 13) has an absorption—weighted with an energy of the radiation—for radiation having an energy in a range from less than the lower bandgap to one spectral end of a relevant incident spectrum of less than 15%, or
c) the optical component (11, 12, 13) has an emission of radiation in a mid-infrared range.

12. The multiple solar cell (1) as claimed in claim 1, wherein
the partial cells (2, 3) are contacted by contacts at the side facing away from the light.

13. The multiple solar cell (1) as claimed in claim 1, wherein
the mean spacing (X) of the structural elements (8) is at least one of less than or equal to 1.2 times the spacing value (A) or greater than or equal to 0.8 times the spacing value (A).

14. The multiple solar cell (1) as claimed in claim 1, wherein
the mean spacing (X) is between 230 nm and 450 nm.

15. The multiple solar cell (1) as claimed in claim 1, wherein
a region of the spacing between the structural elements (8) is filled by at least one of a dielectric material, a semiconductor material, a resist.

16. The multiple solar cell (1) as claimed in claim 2, wherein at least one of a)
the partial element (7) and the intermediate layer (4) are formed from the same material, or
b) the partial element (7) is formed by a resist.

17. The multiple solar cell (1) as claimed in claim 2, wherein
in that a region of the spacing between the structural elements (8) is filled by the at least one separating layer (9).

18. The multiple solar cell (1) as claimed in claim 2, wherein
the structural elements (8) have a mean spacing (X) which is less than a wavelength assigned to the lower bandgap.

19. The multiple solar cell (1) as claimed in claim 2, wherein at least one of a)
least one separating layer (9) is conductive, or
in that b) for the contacting of the intermediate layer (4), point contacts (16) are formed between the intermediate layer (4) and the lower mirror element (6).

20. The multiple solar cell (1) as claimed in claim 2, wherein
the at least one separating layer (9) is formed from a semiconductor material, or
the at least one separating layer (9) is formed from a preferably transparent dielectric material.

21. The multiple solar cell (1) as claimed in claim 2, further comprising
a planarization layer (10) arranged between the at least one separating layer (9) and the lower mirror element (6), the planarization layer (10) being formed from a polymer or from a dielectric or a transparent conductive oxide.

22. The multiple solar cell (1) as claimed in claim 2, wherein at least one of the separating layer (9) or the planarization layer (10) has a thickness of between 100 nm and 300 nm, the thickness for the separating layer (9) resulting from a spacing between an end of the structural element (8) facing away from the light and the lower mirror element (6) or the planarization layer (10).

23. The a multiple solar cell (1) as claimed in claim 1, therein the multiple solar cell (1) is part of at least one of extraterrestrial systems, terrestrial concentrator systems, and/or flying objects, vehicles, or thermophotovoltaics.
